(19) United States
(12) Patent Application Publication
(10) Pub. No.: US 2024/0361361 A1
(43) Pub. Date: Oct. 31, 2024

(54) DEVICES AND METHODS FOR AN ELECTRO-OPTIC DUAL CRYSTAL VOLTAGE SENSOR

(71) Applicant: MICATU INC., Horseheads, NY (US)

(72) Inventors: David Burdick, Corning, NY (US); James Kennedy, Corning, NY (US); Michael Oshetski, Horseheads, NY (US); Atul Pradhan, Pittsford, NY (US)

(21) Appl. No.: 18/632,861

(22) Filed: Apr. 11, 2024

Related U.S. Application Data
(60) Provisional application No. 63/498,769, filed on Apr. 27, 2023.

(51) Int. Cl. G01R 15/24

(52) U.S. Cl. CPC G01R 15/242; G01R 15/247

(57) ABSTRACT

An optical voltage measurement system can include a pickoff rod, a sled, and optical componentry. The pickoff rod can be electrically connected to a power line and configured to emanate an electric field commensurate with the power line's energy. The sled can align and maintain the optical componentry in a fixed orientation to the pickoff rod. The optical componentry can include a dual RTP crystal assembly.

### CROSS-REFERENCE TO RELATED APPLICATION

This application claims priority from U.S. Provisional Application No. 63/498,769, filed Apr. 27, 2023, the disclosure of which is incorporated herein by reference in its entirety.

### TECHNICAL FIELD

The present disclosure relates to the technical field of optical componentry. More particularly, the present technology is related to assemblies for aligning and constructing high-precision optical sensors based on the Pockels effect for detecting and measuring electric fields and voltage on utility high voltage power lines and power distribution networks.

### BACKGROUND

The ability to detect electric fields is important in a number of industries. In the utility industry, for example, detection of electric fields is necessary to measure voltage potential and current. In addition to measurement of electrical properties, detection of electric fields is important in industrial deployments in which ensuring that systems are de-energized is critical for safety. In such environments, it is not always important that absolute values of electric fields (e.g., voltage) be measured, only that their presence be accurately detected.

Electric field detection is of primary importance in the electrical utility industry, where voltages and currents must be monitored at generation source, on transmission grids, on distribution grids, and at final electrical circuits. Detecting and measuring electric fields at these locations is paramount in ensuring that electricity is transmitted through the grid to end users at the correct voltage. In addition to measuring electric fields for the delivery of electricity, there is a need within the utility industry to detect electric fields during inclement climatic and meteorological conditions. In such conditions the environmental or air temperature can vary greatly.

Historically, measurement of medium voltage at distribution substations has been accomplished using iron-core ferro-magnetic voltage transformers. Such technologies, however, inherently disturb the Electromagnetic Field (EMF) associated with medium voltage transmission measurement and actively interfere with the voltage to be determined, thereby compromising the measurement of voltage indirectly. These conventional measurement devices also have associated risks and danger due to arcing, flash, partial discharge, explosions, and catastrophic failure.

### SUMMARY

An aspect can include an optical voltage measurement system. The system can include a pickoff rod, a sled, and optical componentry. The pickoff rod can be electrically connected to a power line and configured to emanate an electric field commensurate with the power line's energy. The sled can align and maintain the optical componentry in a fixed orientation to the pickoff rod. The optical componentry can include a dual RTP crystal assembly.

An embodiment can include a ground cage. The ground cage can be configured to increase the strength of the electric field emanating from the pickoff rod at the position of the optical componentry. The distal end of the pickoff rod (i.e. the end opposite its end connected to the power line) can be hemispherical.

In an embodiment, the sled can include a ceramic sled body having a central chamber for holding the optical componentry. The sled can be of a cycloaliphatic epoxy. The sled can include an input port for receiving a light beam and an output port for transmitting the light beam. The input port and the output port can be collinear along a light beam path. A sled cover can be configured to mate with the ceramic sled body and/or seal the central chamber. The central chamber can have a flat surface parallel to the light beam path.

In another embodiment, the dual RTP crystal assembly can include a first crystal aligned along the light beam path, a quarter-wave plate aligned along the light beam path, a second crystal aligned along the light beam path, and/or a half-wave plate aligned along the light beam path.

Another embodiment can include a line pole insulator. The insulator can be a hollow barrel having a cavity. A ground cage can be configured within the cavity to increase electric field strength from the pickoff rod impinging on and through the optical componentry. The ground cage can be a metallic liner disposed on an inner portion of the line post insulator. The line post insulator can be configured to provide environmental protection to the sled.

An embodiment can include optical fibers for carrying light to and/or from the optical componentry disposed within the sled.

Yet another embodiment can include an optical detector. The detector can be, for example, a photodiode. The optical componentry can be configured to physically sense a voltage and/or an electric field. Light, for example from an external fiber optic, can pass through the optical componentry and change in character, based on the voltage and/or electric field sensed by the optical componentry. The optical detector can detect the resulting change in character and output a signal correlated to the change in character. The output signal can be received by, for example, an analog-to-digital converter, which in turn can output a digital signal to a processor or digital signal processor, which in turn can provide measurement data.

### BRIEF DESCRIPTION OF THE DRAWINGS

The present invention is further described in the detailed description, which follows, in reference to the noted plurality of drawings by way of non-limiting examples of certain embodiments of the present invention, in which like numerals represent like elements throughout the several views of the drawings, and wherein:

FIG. 1 depicts an isometric exploded assembly view of an opto-mechanical ceramic sled with optical components including the RTP crystals, optical waveplates, and polarizing collimators.

FIG. 2 depicts a front view of a ceramic sled body.

FIG. 3 depicts an isometric view of a ceramic sled body.

FIG. 4 depicts an isometric exploded and assembled view of a ceramic sled with optical components.

FIG. 5 shows a simulation of the rendered optical components within the electric field emanating from a pickoff rod within a sensor body.

FIG. 6 shows idealized electric field lines incident on optical components contained in an opto-mechanical ceramic sled assembly within the base of a line-hanging voltage sensor body.

FIG. 7a shows a line hanging sensor body clamped to a high voltage power line.

FIG. 7b shows a line hanging sensor body in cross-section and an opto-mechanical ceramic sled assembly contained inside.

### DETAILED DESCRIPTION

A detailed explanation of the apparatus, systems, methods, and exemplary embodiments of the present invention are described below. Numerous specific details are set forth in order to provide a thorough understanding of embodiments of the invention. However, it will be understood by ordinary artisans that embodiments of the present invention may be practiced without these specific details. In other instances, well-known methods, procedures, and components have not been described in detail so as not to obscure the present invention. Exemplary embodiments described, shown, and/or disclosed herein are not intended to limit any claim, but rather, are intended to instruct the ordinary artisan as to various aspects of the invention. Other embodiments can be practiced and/or implemented without departing from the scope and spirit of the invention.

In view of the challenges inherent in electromagnetic voltage measurement technology, optical sensors can be utilized for medium and high-voltage environments, as well as for low-voltage applications. Such sensors can be immune to electromagnetic and radio frequency interference, with no inductive coupling or galvanic connection between the sensor head on high-voltage lines and power transmission substation electronics. The wide bandwidth of optical sensors can provide for fast fault and transient detection and power quality monitoring and protection. Optical sensors can be easily installed on, or integrated into, existing substation infrastructure and equipment such as circuit breakers, insulators, or bushings resulting in significant space saving and reduced installation costs with no environmental impact.

Optical voltage sensors can utilize the Pockels effect, which is also referred to as the linear electro-optic effect, and include a polarizer at the input and a beam splitter at the output. Traditionally, such devices can function well at constant temperature. However, significant temperature, humidity, and environmental weather swings can impact the accuracy of those devices. Thus, environmental stability can impact the reliability of those optical voltage sensors, particularly with regard to sensitivity due to temperature and humidity of the environment surrounding the optical system or assembly

Passive optical and opto-mechanical alignment techniques are used for aligning series of small and miniaturized optical components such as fiber-optics, lenses and collimators, and crystal elements prior to and without introducing light in the system associated with the optical assembly's function use. Using passive alignment methods can significantly reduce manufacturing time and cost by avoiding complex procedures necessary for powering or introducing light for functional use of the optical assembly and monitoring of light output or signals in an actively aligned method or system. Moreover, in said mixed optical element systems involving crystals and polarization directions of light with projections on crystal axes and planes, passive optical alignment methods that fixate and secure optical elements in the optomechanical assembly, are essential to ensure functional performance over temperature of the optical assembly when actively powered. Such thermal performance is only achieved if the optical elements, once fixated and secured, say at a given starting temperature (e.g. room temperature), do not subsequently move or change their positions and orientations relative to the crystal optical axes, and beam direction of light.

Using conventional electrical transformer-based methods to detect and measure high voltage on power also requires challenging trade-offs and compromises to physical size and placement limits that generally must optimize important safety limit criteria attributes such as strike, creepage and clearance distances, as well as Basic Insulation Level (BIL).

Optical voltage sensors can minimize and obviate challenges vis-à-vis traditional transformer-based voltage sensors. Optical voltage sensors based on the Pockels effect can also be used with electro-optic crystals to the effect of obtaining stability over temperature and associated environmental conditions. This advantageous feature is achieved by utilizing dual crystals that cancel birefringence yet additively double the Pockels effect by precise orientation of crystal axes relative to the optical axis of the crystal and direction of propagation of light. An example of such an optical assembly is described in U.S. Provisional Patent Application No. 63/338,223 (“Reference 1”), which is incorporated by reference herein in its entirety.

Opto-mechanical mounting and sealing technology can be advantageously utilized to provide stable performance across operating temperature and environmental conditions. Such hermetic type sealing additionally prevents ingress of moisture, water condensation, and other deleterious contaminants that can affect sensitive polarization based optical performance.

Optical voltage sensors can utilize elaborate polarization diversity schemes that involve various optical components dedicated to polarization manipulation of phase and rotation. Typically, such polarization components, such as wave plates, retarders, and beam splitters have been fragile and can vary greatly over temperature and environmental conditions and change the phase of the optical beam and resultant signal.

FIG. 1 illustrates an opto-mechanical diagram of an exemplary optical electric field sensor assembly (100). An input fiber-coupled polarizing collimator (101) can define the path of light propagation incident on a first crystal (102) and also through a second crystal (103). An output polarizing collimator (104) can act an analyzer after the second crystal (103) receives and couples light to an output fiber.

Input polarization, as set by the input polarizer (101), and output polarization, as analyzed at the output polarizer (104), can be optimally oriented relative to the crystal axes, as described in Reference 1. The input polarizer (101) and output polarizer (104), utilized in the present illustrative embodiment as polarizing collimators (i.e., polarizers coupled to collimator lenses), are described in U.S. Pat. No. 10,175,425 (“Reference 2”), which is incorporated by reference herein in its entirety. As a skilled artisan will appreciate, alternative embodiments are possible, and combinations of other types of polarizers and collimators can also be used in other examples, without loss of generality, achieving substantially similar functionality and without departing from the spirit of the invention. For example, a device can include an optical fiber, a fiber ferrule, a collimating lens, a polarizer element, and a housing. The device may include other types and numbers of elements or components in other configurations, including additional optics such as lenses, prisms, or filters, by way of example only. Additional optics may be utilized, by way of example, to redirect, focus, collimate, or filter the wavelength of light within the device.

The temperature dependence of the Pockels effect in the first and second crystals 102 and 103 is substantially linear. However, it can be obscured by birefringence in the first and second crystals (102, 103) due to coefficient of thermal expansion (CTE) induced changes and associated temperature dependent stress.

The combined optical phase of polarized light in the direction of propagation through the first and second crystals (102 and 103, respectively) is in generally is given by Γ=β+ϕ, where β is the birefringence phase and ϕ is the Pockels effect phase. The technology described and illustrated by way of the examples herein advantageously substantially eliminates the temperature dependent birefringence phase β by orienting crystal axes so that accumulation of the Pockels effect phase of the crystals ϕ is additive and the birefringence phases is subtractive as is described in detail in Reference 1.

The first and second crystals (102, 103) can advantageously comprise rubidium titanyl phosphate (RbTiOPO₄) (RTP).

In a preferred embodiment (100), a ceramic sled holder (105) can hold and align a series of optical components for use in, e.g., laser systems. The ceramic sled body can be designed to securely hold and align RTP crystals (102, 103) and waveplates (106, 107) to manage polarization diversity and optical phase of the light propagation. The ceramic sled body can be made from a high-strength ceramic material that is both durable and resistant to thermal stresses. The ceramic material can be chosen to have a low coefficient of thermal expansion, which can ensure that the sled body maintains its shape and alignment even when subjected to changes in temperature.

The componentry of the embodiment in FIG. 1 embodiment can be assembled directly in the ceramic sled body. Each RTP crystal and waveplate can have a slight air gap between them and their neighboring optical components running along the optical axis. An air gap can reduce thermal stresses on the RTP crystals and waveplates by allowing thermal expansion and contraction without touching neighboring optical components. An air gap can allow for slight variances in the dimensions of the RTP crystals and/or waveplates.

The RTP crystals (102, 103) can be a matched pair of crystals with optical crystals axes aligned to the direction of light propagation. In this preferred embodiment, the dimensions of the crystals are 10 mm×4 mm×5.3 mm with light propagation along the 5.3 mm axis. Waveplates are included in the assembly to manage polarization diversity and orientation of the crystals towards the electric field, so that the Pockels optical phase that senses the electric field and associated voltage drop across the crystals is maximized. The RTP crystals can be advantageously coated with metals along the surfaces defining the voltages drop, as depicted in Reference 1, to further maximize the optical phase sensing of the electric field permeating the RTP crystals (102, 103) and the associated voltage drop across the crystals.

The ceramic sled body can further include a probe (108) and/or other sensing devices to measure temperature. The probe can be fiber-optic based. As will be understood by those knowledgeable in the art, optical fibers and waveguides are available in several types and configurations depending on the application and wavelength range of the light of interest. Examples can include index guiding glass, ceramic, or plastic fibers, with a core and cladding. Either step, continuous, or multiple refractive index claddings can be utilized for optical fibers. In addition, glass, ceramic, plastic, and metal hollow core fibers, photonic bandgap, or photonic crystal fibers can be used as part of the optical fibers. The optical fibers can include a single mode optical fiber, although multimode fibers may also be employed. According to one example, the use of a multimode fiber for the optical fiber can allow for a high number of modes of light to propagate in the optical fibers. This can allow for selecting and converting substantially random, or partially polarized, light to linear polarized light.

The ceramic sled body (105) can be sealed by a sled cover (109). The sled cover can be, for example, ceramic and/or resin. The body and cover can be semi-glued and/or mated via bolts. A gasket (not shown) can be utilized to maintain a hermetic seal. A sleeve (110) can be utilized to cover the sled body and sled cover. The sleeve can be semi-glued to the body and cover.

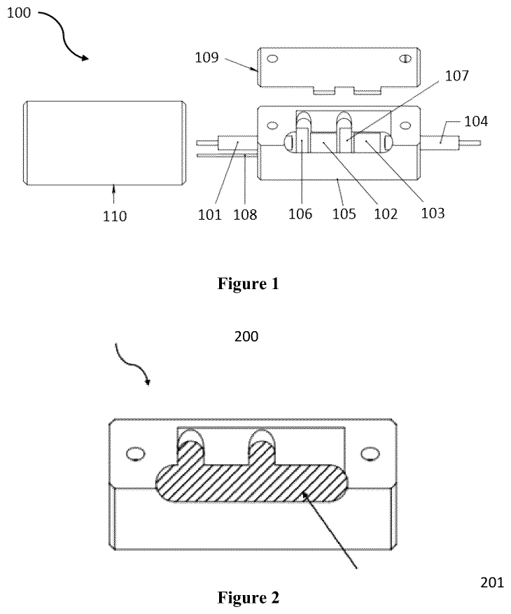

FIG. 2 depicts a front view of an illustrative embodiment of an unsealed sled holder (200). The hashed surface (201) shown in the image represents a flat surface that runs parallel to the optical axis of crystal axes and direction of light and through the wave plates. All the optical components can be adhered to the hatched surface which can serve as datum for passive alignment of the optical components. The crystals can have their respective optical axes aligned, preferably to 10 arc minutes of angular deviation or less. Adhering precision rectangular optical components to a ceramic sled surface that is parallel to the direction of propagation of light and optical axes of the crystal can ensure that the beam will pass through optical surfaces at near perfect perpendicularity.

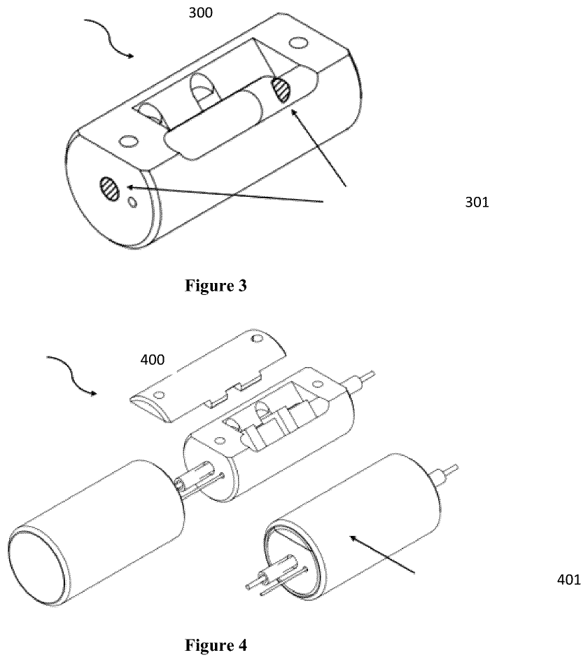

FIG. 3 illustrates an isometric view of the sled body (300). Hatched surfaces (301) illustrate collimator holders which can be machined in a single drilling operation. By using one drilling operation for the collimator bores, the optical axis for both bores can be made collinear. The hatched surfaces shown in the image represent a flat surface that runs parallel to the optical axes of crystals and light direction. The optical components, such as crystals, waveplates, and collimators, can be attached using ultraviolet (UV) curing glue. The optical components can be cut to precise dimensions in order to ensure that their non-optical surfaces are within 10 minutes of arc of perpendicular to the optical surfaces. Precision can be important to ensure passive alignment to avoid variations or tolerance deviation due to, e.g., thermal or environmental excursions.

FIG. 4 illustrates an isometric exploded (400) and assembled (401) view of a ceramic sled with optical components. In this view, all the optical components are shown assembled into the ceramic sled, with the RTP crystals and waveplates attached to the hatched surface using UV-reactive glue. The collimators are inserted into the collimator holders, which can be machined into the ceramic sled body.

While the discussion above focuses primarily on a preferred ceramic sled body, other materials can be utilized, such as metal or plastic. However, it is important to note that the material used for the sled body should have sufficient thermal stability and rigidity to ensure accurate alignment of the optical components. Additionally, while RTP crystals and waveplates are specifically discussed, other types of optical components could be used instead, such as lenses, prisms, or mirrors. The specific choice of optical components will depend on the particular application and desired performance characteristics.

Regarding assembly of the optical components onto the sled body, alternative methods of attachment can be used instead of UV-reactive glue, such as mechanical fasteners and/or thermal bonding. The choice of attachment method will depend on the specific requirements of the application. There are several types of UV glue that can be used for adhering the optical components to the sled body. For example, acrylic UV glue has a fast cure time and forms a strong bond that is resistant to impact and temperature changes. Epoxy UV glue has a longer cure time but forms a strong and durable bond that can withstand high temperatures and harsh environments. Silicone UV glue has a flexible bond that can absorb stress and vibration, making it ideal for applications where the sled and optical components will be exposed to movement or mechanical stress. Polyurethane UV glue is a tough and durable adhesive that is resistant to impact and temperature changes, making it suitable for rugged applications. Cyanoacrylate UV glue has a fast cure time and forms a strong bond that is resistant to impact and temperature changes. The specific type of UV glue that is chosen will depend on the specific requirements of the application, such as cure time, bond strength, temperature resistance, and flexibility.

Furthermore, the shape and size of the sled body and optical components can be modified to suit different applications. For example, the sled body could be made larger or smaller to accommodate different numbers or sizes of optical components. Similarly, the shape and size of the optical components themselves could be varied to achieve specific optical properties.

Coatings and/or surface treatments can be applied to components and the sled body to enhance performance characteristics, such as anti-reflective coatings to the optical components improved optical throughput or coatings on the sled to modify or optimize thermal conductivity for the application. The specific choice of coatings will depend on the desired performance characteristics and the operating environment of the device. The dielectric constant or relative permittivity of the materials that contain the ceramic sled may also be chosen to optimize the electric field impinging and permeating into the optical component RTP crystals within the sled body in order to maximize sensitivity and determination of the voltage on the high voltage power distribution line.

Opposite surfaces of the RTP crystals can be oriented such that a normal to said surfaces has a projection that is normal to the direction of light propagation through the crystal. Equivalently, any line that exists within the planes of said surfaces will have a projection that is parallel to the direction of light.

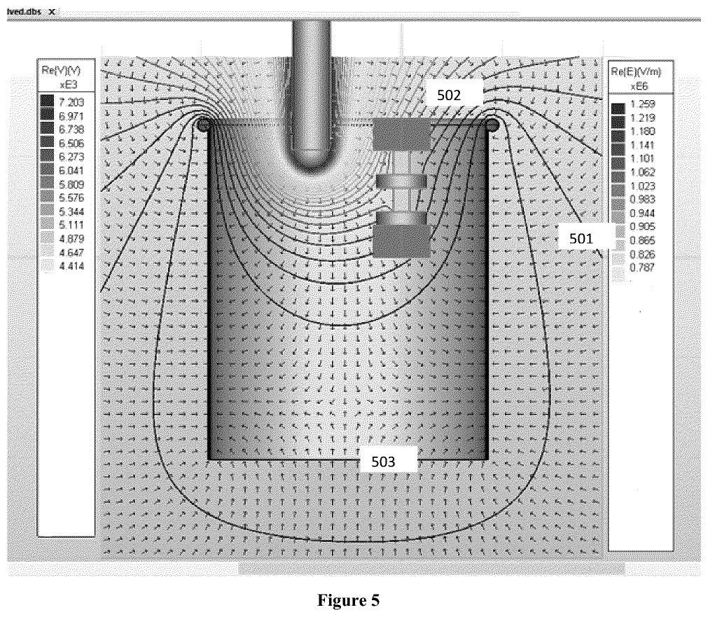

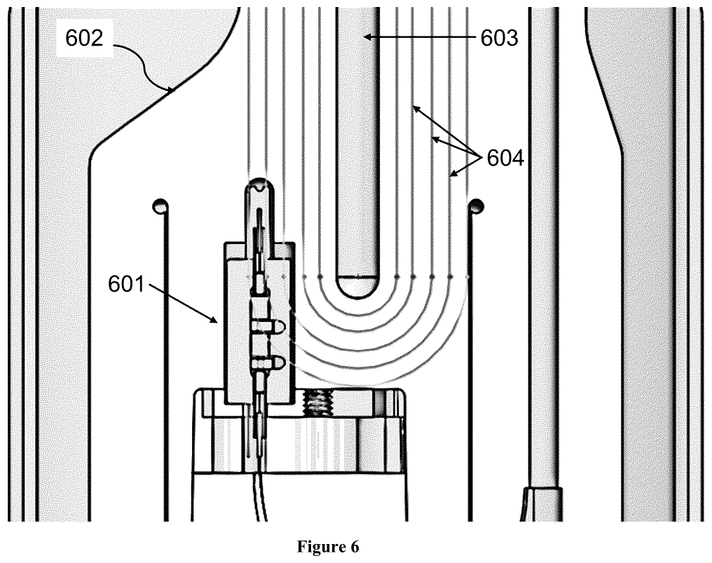

FIG. 5 shows an electrodynamic simulation, using Coulomb electrodynamics software, of the rendered optical components within the electric field emanating from the pickoff rod within the sensor body. The optical assembly and constituent optical components (501) are shown in proximity to the end portion of the pickoff rod that extends back and is attached to the clamping mechanism to the high-voltage power line. Electric field intensity and direction are shown as well as contour lines of equal electric potential. A ground cage (503) can be advantageously utilized to adjust to channel the contour lines of potential to maximize the electric field impinging on and through the optical crystal elements and thereby maximize the voltage drop across the surfaces of the crystal normal to the direction of propagation of light.

FIG. 6 shows a cross-section of the optical assembly contained in the ceramic sled (601) which is installed within a cavity (602) in proximity to the high voltage pickoff rod (603) with idealized electric potential lines (604) shaped by the ground cage. The idealized electric field lines are incident on the optical components and crystals contained in the opto-mechanical ceramic sled assembly within the base portion of a line-hanging voltage sensor body that is composed of resin, plastic, ceramic, or other non-metallic materials, for example, in this embodiment advantageously, cycloaliphatic epoxy. A fiber-optic cable serves a conduit from outside the sensor body through the base for light propagation up to the launch polarizing collimator.

Here, the Pockels effect phase is dependent on the time varying voltage V (t), on the high voltage power line, which is the object of measurement. The output polarizer polarizing collimator in the optical assembly is configured to resolve and superpose polarization components exhibiting differential optical phase. This produces light with an optical phase amplitude that will exhibit a time varying optical intensity modulation, which can be detected, via exit fiber optic cable, on an electro-optic receiving photodiode by a device or unit external to the sensor body and remotely installed such as a modular optical device or unit as in U.S. Pat. No. 10,623,099 (“Reference 3”), which is incorporated by reference herein in its entirety.

The expression for the optical transmission through the optical voltage assembly due to the Pockels effect phase can be represented as in a transverse Pockels cell modulator. With reference to the direction of light, through the crystals that sense the electro-optic Pockels effect as described in the optical assembly, the optical intensity at the exit polarizing collimator, which acts as an optical analyzer, is given by the expression:

$$T = {sin}^{2} ( V / {V}_{π} + ϕ )$$

where V_{π} is the half wave voltage, and V is the voltage drop between opposite surfaces of the RTP crystals upon which the electric field is incident and ϕ is an arbitrary phase factor, that can be computed in a time varying optical modulation detection scheme by the external optical telemetry device or unit.

The optical voltage assembly can be coupled by fiber-optic cable to one or more detectors (e.g., photodiodes) as part of the optical telemetry unit. In particular, the fiber-optic light output that is detected electro-optically using the optical telemetry unit (Reference 2) is converted to an electrical signal to which sophisticated digital signal processing (DSP) algorithm can be applied to improve accuracy.

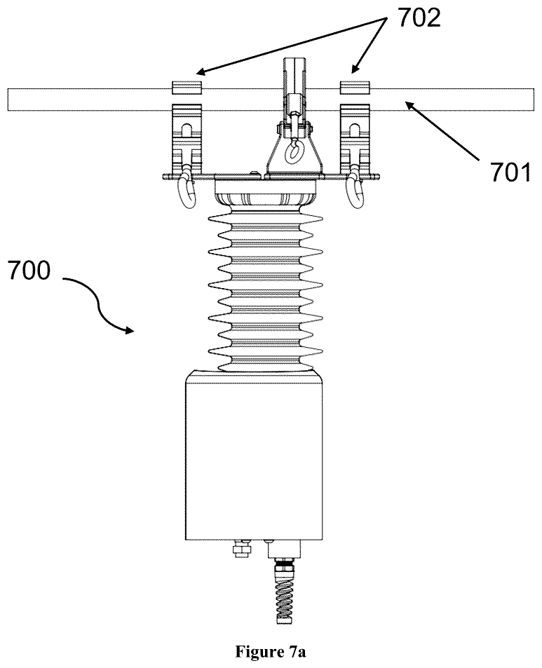

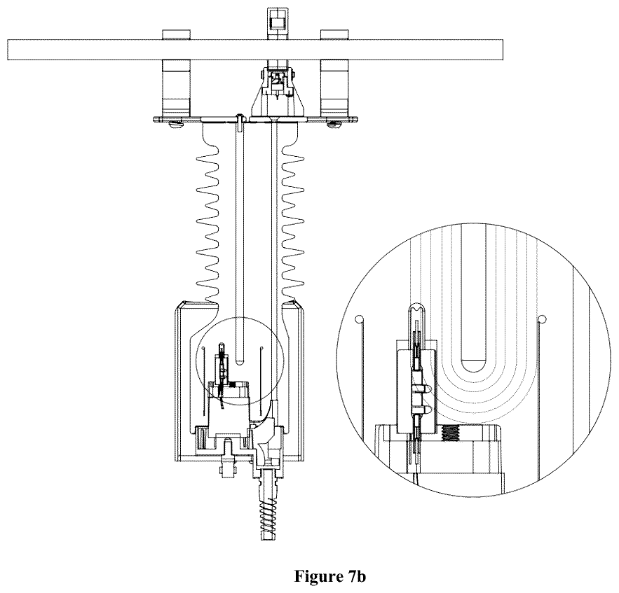

FIG. 7a shows an entire sensor body (700) attached to a high-voltage power line (701) using clamps (702) which is secured to a base plate below which the cycloaliphatic sensor body is suspended. FIG. 7b shows a cross section of the suspended sensor body showing the pickoff rod with a secured attachment to the base plate and the hemispherical end point in proximity to the embedded optical voltage assembly with an exploded inset view as in FIG. 6. The hemispherical end point of the pickoff rod will thus be at the same voltage and potential as the high voltage-power line and serve as the source of the electric field impinging and permeating the optical voltage assembly containing the dual electro-optic crystals.

Although the methods and devices are described herein with a focus on line-hanging sensor embodiments, the sensor systems described herein are equally applicable, without loss of generality, to line post, platform, underground, and other similar sensors. As the skilled artisan will appreciate, the sensor systems described herein can be utilized with computer systems to yield measurement data. For example, sensor output can be coupled to an analog detector, such as a photodiode. Analog signals can be converted, such as by an analog-to-digital converter. Resultant digital signals can be fed to a processor or a digital signal processor, which can provide digital measurement data for downstream practical use.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. An optical voltage measurement system, comprising:
a pickoff rod electrically connected to a power line and configured to emanate an electric field commensurate with the power line's energy;
a sled for aligning and maintaining optical componentry in a fixed orientation to the pickoff rod; and
wherein the optical componentry comprises a dual RTP crystal assembly.

2. The optical voltage measurement system of claim 1, further comprising a ground cage to increase electric field strength impinging the optical componentry.

3. The optical voltage measurement system of claim 1, wherein the sled comprises a ceramic sled body having a central chamber for holding the optical componentry, an input port for receiving a light beam, and an output port for transmitting the light beam; and
wherein the input port and the output port are collinear along a light beam path.

4. The optical voltage measurement system of claim 3, further comprising a sled cover configured to mate with the ceramic sled body and seal the central chamber.

5. The optical voltage measurement system of claim 4, wherein the central chamber has a flat surface parallel to the light beam path.

6. The optical voltage measurement system of claim 1, wherein the dual RTP crystal assembly comprises a first crystal aligned along the light beam path, a quarter-wave plate aligned along the light beam path, a second crystal aligned along the light beam path, and a half-wave plate aligned along the light beam path.

7. The optical voltage measurement system of claim 1, wherein the sled comprises cycloaliphatic epoxy.

8. The optical voltage measurement system of claim 6, further comprising a line pole insulator having a cavity; and
a ground cage configured to increase electric field strength impinging the optical componentry, wherein the ground cage comprises a metallic liner disposed on an inner portion of the line post insulator.

9. The optical voltage measurement system of claim 1, further comprising a fiber-optic cable to transmit light to the sled.

10. The optical voltage measurement system of claim 1, wherein the pickoff rod has an end distal to the power line, wherein the distal end is hemispherical.

11. The optical voltage measurement system of claim 8, wherein the line post insulator is configured to provide environmental protection to the sled.

12. The optical voltage measurement system of claim 3, further comprising an optical detector;
wherein the optical componentry is configured to physically sense a voltage and the electric field; and
wherein the optical detector is configured to detect the voltage and the electric field.
